(19) United States
(12) Patent Application Publication
(10) Pub. No.: US 2012/0139001 A1
(43) Pub. Date: Jun. 7, 2012

(54) Method For Producing An Organic Optoelectronic Component And Organic Optoelectronic Component

(76) Inventors: Angela Eberhardt, Augsburg (DE); Tilman Schlenker, Nittendorf (DE); Marc Philippens, Regensburg (DE); Ulrike Beer, Meitingen (DE); Joachim Wirth-Schoen, Guenzburg (DE); Florian Peskoller, Ingolstadt (DE); Ewald Poesl, Kissing (DE)

(21) Appl. No.: 13/141,081

(22) PCT Filed: Dec. 10, 2009
(86) PCT No.: PCT/EP2009/066843

§ 371 Date: Feb. 23, 2012

(30) Foreign Application Priority Data
Dec. 18, 2008 (DE) 1020080636363

(51) Int. Cl. H01L 51/52; H01L 51/56

(52) U.S. Cl. 257/99; 438/46; 257/40; 257/E51.018

(57) ABSTRACT

Production of an organic optoelectronic component comprising the following steps: A) providing a first substrate (1) having an active region (12) and a first connection region (11) surrounding said active region (12), wherein an organic, functional layer sequence (3) is formed in said active region (12), B) providing a second substrate (2) having a cover region (22) and a second connection region (21) surrounding said cover region (22), C) applying a first connection layer (4) made from a first glass solder material directly to said second substrate (2) in said second connection region (21), D) vitrifying (91) said first glass solder material of said first connection layer (4), E) applying a second connection layer (5) to said vitrified first connection layer (4) or to said first connection region (11) of said first substrate (1) and F) connecting said first substrate (1) to said second substrate (2) such that said second connection layer (5) connects said first connection region (11) to said first connection layer (4). The invention furthermore relates to an organic optoelectronic component.

This patent application claims the priority of German patent application 102008063636.3, the disclosure content of which is hereby incorporated by reference.

A method for producing an organic optoelectronic component and an organic optoelectronic component are specified.

For permanent and reliable operation of organic light-emitting diodes (OLED), it is necessary to seal the latter for protection against oxygen and moisture. For this purpose, the oxygen- and/or moisture-sensitive structural parts of an OLED can be arranged between two glass plates that are connected by means of an adhesive extending around the structural parts, as a result of which an encapsulation is formed. The adhesive usually contains fillers in the form of beads or fibers which, as spacers, for example, provide for a defined distance between the two glass plates. Since the adhesive is typically not totally impermeable to oxygen and water vapor, however, these gases can diffuse through the adhesive into the OLED over time.

It is an object of at least one embodiment to specify a method for producing an organic optoelectronic component. It is an object of at least one further embodiment to specify an organic optoelectronic component.

These objects are achieved by means of the method and the article of the independent patent claims. Advantageous embodiments and developments of the article and of the method are characterized in the dependent claims and will furthermore become apparent from the following description and the drawings.

A method in accordance with one embodiment for producing an organic optoelectronic component comprises, in particular, the following steps:

A) providing a first substrate having an active region and a first connection region surrounding the active region, wherein an organic functional layer sequence is formed in the active region,

B) providing a second substrate having a covering region and a second connection region surrounding the covering region,

C) applying a first connection layer composed of a first glass solder material directly on the second substrate in the second connection region,

D) vitrifying the first glass solder material of the first connection layer,

E) applying a second connection layer on the vitrified first connection layer or on the first connection region of the first substrate, and

F) connecting the first substrate to the second substrate in such a way that the second connection layer connects the first connection region to the first connection layer.

In accordance with a further embodiment, an organic optoelectronic component comprises, in particular,
a first substrate having an active region and a first connection region surrounding the active region, wherein an organic functional layer sequence is formed in the active region,
a second substrate having a covering region above the active region and a second connection region, surrounding the covering region above the first connection region, and
a first and a second connection layer between the first and second connection regions,

wherein
the first connection layer directly adjoins the second connection region and is composed of a first glass solder material, and
the second connection layer connects the first connection layer to the first connection region.

The embodiments, features and combinations thereof that are described below relate equally to the organic optoelectronic component and to the method for producing the organic optoelectronic component, unless explicitly noted to the contrary.

In this case, the fact that one layer or one element is arranged or applied “on” or “above” another layer or another element can mean here and hereinafter that said one layer or said one element is arranged directly in direct mechanical and/or electrical contact on the other layer or the other element. Furthermore, it can also mean that said one layer or said one element is arranged indirectly on or above the other layer or the other element. In this case, further layers and/or elements can then be arranged between said one layer and the other layer or between said one element and the other element.

The fact that one layer or one element is arranged “between” two other layers or elements can mean here and hereinafter that said one layer or said one element is arranged directly in direct mechanical and/or electrical contact or in indirect contact with one of the two other layers or elements and in direct mechanical and/or electrical contact or in indirect contact with the other of the two other layers or elements. In this case, in the case of indirect contact, further layers and/or elements can then be arranged between said one layer and at least one of the two other layers or between said one element and at least one of the two other elements.

If, in method step E, the second connection layer is applied on the first connection layer and on the first substrate, then that can mean, in particular, that one part of the second connection layer is applied on the first connection layer and a further part of the second connection layer is applied on the first substrate, which are then joined together to form the actual second connection layer in method step F. In method step E, the second connection layer can be applied, in particular, directly on the first connection layer and/or directly on the first substrate. Thus, the second connection layer in the finished organic optoelectronic component can directly adjoin the first connection layer and directly adjoin the first substrate and have in each case a common interface with them.

Here and hereinafter, “optoelectronic” can denote the property, in particular, of converting electromagnetic radiation or light into an electric voltage and/or an electric current and/or converting an electric voltage and/or an electric current into electromagnetic radiation or light. Consequently, the organic optoelectronic component can be embodied in the first case as an organic radiation-receiving or radiation-detecting component, for instance an organic photodiode or solar cell, and in the second case as an organic radiation-emitting component, for instance an organic light-emitting diode (OLED). Here and hereinafter, “light” or “electromagnetic radiation” can equally denote, in particular, electromagnetic radiation having at least one wavelength or a wavelength range from an infrared to ultraviolet wavelength range. In this case, the light or the electromagnetic radiation can comprise a visible, that is to say a near-infrared to blue, wavelength range having one or a plurality of wavelengths between approximately 350 nm and approximately 1000 nm.

By virtue of the fact that the first connection layer composed of the first glass solder material is arranged between the first substrate and the second substrate, an encapsulation that is more impermeable to oxygen and moisture and water vapor can be provided in comparison with a known OLED comprising a pure adhesive layer.

In particular, the second substrate or else the first and the second substrates can comprise a glass, for example comprising a silicate glass, such as, for instance, borosilicate glass or aluminosilicate glass, and/or quartz glass, or some other glass material suitable for organic components.

Particularly preferably the optoelectronic component can be embodied as an organic light-emitting diode (OLED). The OLED can have, in the active region, for example, a first electrode on the first substrate. An active layer having one or a plurality of functional layers composed of organic materials can be applied above the first electrode. In this case, the functional layers can be formed for example as electron transport layers, hole blocking layers, electroluminescent layers, electron blocking layers and/or hole transport layers. A second electrode can be applied above the functional layers. In the functional layers, electromagnetic radiation having an individual wavelength or a range of wavelengths can be generated by electron and hole injection and recombination. In this case, an observer can be given a single-colored, a multicolored and/or a mixed-colored luminous impression.

In particular, the first electrode and/or the second electrode can be embodied particularly preferably in areal fashion or alternatively in a manner structured into first and/or second electrode partial regions, respectively. By way of example, the first electrode can be embodied in the form of first electrode strips arranged parallel alongside one another, and the second electrode as second electrode strips arranged parallel alongside one another and running perpendicularly to said first electrode strips. Overlaps of the first and second electrode strips can thus be embodied as separately drivable luminous regions. Furthermore, it is also possible for only the first or the second electrode to be structured. Particularly preferably, the first and/or the second electrode or electrode partial regions are electrically conductively connected to first conductor tracks. In this case, an electrode or an electrode partial region can, for example, merge into a first conductor track or be embodied separately from a first conductor track and be electrically conductively connected thereto. The conductor tracks can be led out from the active region and the first connection region between the first substrate and the second connection layer, such that electrical contact can be made with the organic functional layer sequence outside the first connection region.

If the organic optoelectronic component is embodied as an OLED and, in this case, in particular as a so-called “bottom emitter”, that is to say that the radiation generated in the organic functional layer sequence is emitted through the first substrate, then the first substrate can advantageously have a transparency to at least part of the electromagnetic radiation generated in the active layer.

In the bottom emitter configuration, the first electrode can also have a transparency to at least part of the electromagnetic radiation generated in the active layer. A transparent first electrode, which can be embodied as an anode and thus serves as hole injecting material, can for example comprise a transparent electrically conductive oxide or consist of a transparent conductive oxide. Transparent electrically conductive oxides (transparent conductive oxides, “TCO” for short) are transparent, conductive materials, generally metal oxides, such as, for example, zinc oxide, tin oxide, cadmium oxide, titanium oxide, indium oxide, or particularly preferably indium tin oxide (ITO). Alongside binary metal-oxygen compounds such as, for example, ZnO, SnO₂ or In₂O₃, ternary metal-oxygen compounds such as, for example, Zn₂SnO₄, CdSnO₃, ZnSnO₃, MgIn₂O₄, GaInO₃, Zn₂In₂O₅ or In₄Sn₃O₁₂ or mixtures of different transparent electrically conductive oxides also belong to the group of TCOs. Furthermore, the TCOs need not necessarily correspond to a stoichiometric composition and can also be p- or n-doped.

The functional layers can comprise organic polymers, organic oligomers, organic monomers, organic small, non-polymeric molecules (“small molecules”) or combinations thereof. Suitable materials and arrangements and structurings of the materials for functional layers are known to the person skilled in the art and will therefore not be explained any further at this juncture.

The second electrode can be embodied as a cathode and thus serve as electron injecting material. Inter alia, in particular, aluminum, barium, indium, silver, gold, magnesium, calcium or lithium and also compounds, combinations and alloys thereof can prove to be advantageous as cathode material. Additionally or alternatively, the second electrode can also be embodied in transparent fashion and/or the first electrode can be embodied as a cathode and the second electrode as an anode. That means, in particular, that the OLED can also be embodied as a “top emitter”. In particular, the organic optoelectronic component can be embodied simultaneously as bottom emitter and as top emitter and thus in transparent fashion.

The active region can furthermore comprise features and components for active or passive displays or illumination devices, for instance TFTs.

The first glass solder material can preferably be a glass-like, that is to say amorphous, or crystalline fusible and curable material or composite comprising a plurality of materials, which can furthermore also comprise suitable fillers for example for adapting coefficients of thermal expansion. The first glass solder material, which can also be designated as glass frits, can comprise the actual material to be vitrified and also fillers and can comprise, for example, a mixture of oxides selected from vanadium oxide, phosphorus oxide, titanium oxide, iron oxide, for instance iron(III) oxide (Fe₂O₃), tin oxide, boron oxide, lead oxide, aluminum oxide, alkaline earth metal oxides, silicon oxide, zinc oxide, bismuth oxide, hafnium oxide, zirconium oxide and alkali metal oxides. In particular, the first glass solder material can also be free of lead compounds if this is necessary from standpoints appertaining to environmental technology and compatibility. The first glass solder material can be applied, in particular, as a shapeable glass solder material in a solvent-binder mixture in method step C. By way of example, a mixture of amyl acetate and nitrocellulose is suitable as solvent-binder mixture. Further examples and embodiments of glass solder materials, fillers and mixtures thereof are described in the documents U.S. Pat. No. 6,936,963 B2 and U.S. Pat. No. 6,998,776 B2, the disclosure content of which in this respect is hereby incorporated by reference.

The process of applying the first glass solder material in method step C onto the second connection region of the second substrate can be effected for example as a paste by means of screen printing, stencil printing or dispensing, such that a so-called glass solder bead comprising the first glass solder material surrounds the covering region and is applied directly, that is to say in direct mechanical contact. Afterward, the still shapeable first glass solder material can be dried, subjected to binder removal, sintered and vitrified in a furnace by the supply of heat. As a result, as early as before method step E, a permanent first connection layer that is impermeable to oxygen and moisture can be produced on the second substrate, the interface between said first connection layer and the second substrate likewise being impermeable to oxygen and moisture. As a result of the vitrifying of the first connection layer in a furnace rather than by means of a laser, as in the case of known OLEDs, a more cost-effective and more economically viable production process can be made possible. By vitrifying the first connection layer in a furnace, it is possible for a first glass solder material with a coefficient of thermal expansion adapted to the second substrate to be fused with the second substrate in a stress-free manner, without strains occurring in the first connection layer and/or in the second substrate as a result of known local fusing processes for example by means of laser action. Cost-intensive and complex processing of the second substrate can furthermore likewise be obviated.

The first connection layer can be formed with a first thickness, while the second connection layer is then subsequently formed with a second thickness. The second thickness can be less than or equal to the first thickness. As a result, in comparison with a conventional OLED with a continuous adhesive layer, it is possible to achieve a reduction of the proportion of oxygen- and/or water-vapor-permeable volume for the same width and height of the sealing section, that is to say of the first and second connection layers together, in comparison with the known pure adhesive layer. The smaller the second thickness is made in comparison with the first thickness, the lower the probability becomes that oxygen and/or moisture can diffuse into the active region with the organic optoelectronic layer sequence. Particularly preferably, the distance between the first and second substrates is crucially defined by the first connection layer, which means that the second thickness is less than or equal to one fifth, and preferably less than or equal to one tenth, of the first thickness. Depending on the embodiment of the organic optoelectronic layer sequence and, if appropriate, of a getter layer described further below, the first thickness can preferably have a first thickness of greater than or equal to 5 micrometers, particularly preferably of greater than or equal to 10 micrometers, and less than or equal to 20 micrometers. In particular, a distance between the first and second substrates of 10 micrometers or more is thus possible, which can be advantageous, in particular, by way of example, in the case of large-area organic optoelectronic components, since it is thereby possible to compensate, for instance, for deformations of the first and/or of the second substrate on account of pressure differences between the internal volume of the component with the layer sequence and the surroundings.

The second connection layer can, by contrast, have a second thickness, which is optimized with regard to its connection and adhesion properties. In this case, the second connection layer can have a second thickness of greater than or equal to one or a plurality of atomic layers of the material of the second connection layer and less than or equal to a few micrometers, preferably less than or equal to 5 micrometers, in particular less than or equal to 2 micrometers, and particularly preferably less than or equal to 1 micrometer. In this case, the second connection layer can particularly preferably be free of a spacing-defining filler (“spacer”) material.

The second connection layer can comprise an organic curable adhesive, which can be cured after the process of joining together the first substrate with the second substrate in method step F. In this case, “curing” can denote here and hereinafter the suitable reactions and mechanisms in the adhesive itself and at the respective interfaces between the adhesive and the first connection layer and the first substrate by means of which a permanent connection of the first substrate to the second substrate is made possible. This can include processes such as crosslinking reactions or else evaporation and/or volatilization of solvents. The curing can be brought about by a self-initiated reaction or else by supply of energy externally, in the second case in particular by supply of heat or electromagnetic radiation in particular in the form of ultraviolet or infrared light. The adhesive can comprise, in particular, an organic crosslinkable material or a plurality of such materials, for example siloxanes, epoxides, acrylates, methyl methacrylates, urethanes or derivatives thereof in the form of monomers, oligomers or polymers or furthermore also mixtures, copolymers or compounds therewith. Particularly preferably, the matrix material can comprise or be an epoxy resin and/or be curable by means of UV light.

Furthermore, the second connection layer can comprise or be composed of a second glass solder material. The second glass solder material can have features, properties and combinations thereof as described in connection with the first glass solder material.

In particular, the second connection layer can comprise a material that absorbs electromagnetic radiation, said material being selected from one or more of the materials from the group of the rare earth metals, transition metals, and in particular from the metals iron, copper, vanadium and neodym. By admixing one or a plurality of such absorbent materials with the second connection layer, it is possible to increase the absorptivity for electromagnetic radiation and thus to accelerate the curing of the second connection layer. Furthermore, the first connection layer can be free of the absorbent materials or can have at least a lower concentration thereof, such that a targeted absorption of incident electromagnetic radiation in the second connection layer can be achieved. In particular, absorbent materials in combination with a second connection layer composed of a second glass solder material are suitable since, as a result of the absorbent properties, it is possible to achieve a targeted local heating of the second connection layer, that is to say of the second glass solder material, and thus an improved vitrifying thereof.

After method step F, the second glass solder material of the second connection layer can be vitrified. This can be effected, in particular, by melting the second glass solder material by means of irradiation with ultraviolet or infrared light. The latter can be radiated onto the second connection layer for example by means of a laser or some other suitable radiation source. The above-described smaller second thickness of the second connection layer in comparison with the first thickness of the first connection layer can make it possible that the vitrifying of the second glass solder material does not bring about a large increase in the temperature of the further structural parts of the organic optoelectronic component to be produced. Consequently, the organic optoelectronic layer sequence can be encapsulated at low temperature and without damage to the layer sequence. In this case, the thinner the second connection layer, the easier the melting and vitrifying thereof and the more easily a permanent connection of the second connection layer to the first connection layer and the first substrate can be producible. The already vitrified first glass solder material of the first connection layer can remain highly viscous and particularly preferably solid during the melting and vitrifying of the second glass solder material, apart from in regions of the interface with the second glass solder material, such that the distance between the first substrate and the second substrate can substantially be defined by means of the first thickness of the first connection layer. Particularly preferably, for this purpose the first glass solder material can have a higher melting point than the second glass solder material.

Consequently, the first and second glass solder materials can be different with regard to their compositions and furthermore, in particular, with regard to their melting points.

Furthermore, during or after method step D the first connection layer can be planarized on a surface facing away from the second substrate. This can be effected for example by etching and/or preferably by grinding of the already vitrified first glass solder material or alternatively or additionally also by a corresponding shaping process in the vitrifying process of method step D in the furnace. The planarization can make it possible, for example, to achieve the adhesion of the first connection layer and the second connection layer to one another and also an optimization of the distance between the first and second substrates in the finished component.

Furthermore, in method step A the first substrate can be provided with a depression in the first connection region. In particular, the depression can be embodied in such a way that it surrounds the active region. The depression can be provided for the purpose that after method step F the second connection layer is at least partly arranged in the depression. That can mean that in method step E the second connection layer is at least partly applied in the depression. Alternatively or additionally, in the method step the second connection layer can also be applied on the first connection layer and then, in method step F, during the process of connecting the first substrate to the second substrate, can at least partly be arranged in the depression. The fact that the second connection layer is at least partly arranged in the depression can mean that the depression has a depth which, for example, is less than the second thickness of the second connection layer. In this case, the second connection layer can still project from the depression. The depression can then have a width which can be chosen independently of a width of the first connection layer. As an alternative thereto, the depth of the depression can be greater than or equal to the second thickness of the second connection layer, such that after method step F the second connection layer can be arranged completely in the depression and can thus be surrounded completely by the first substrate and the first connection layer. In particular, in this case, the depression can have a width which is greater than or equal to a width of the first connection layer. In this case, after method step F, the first connection layer can also extend into the depression and thus be partly arranged in the depression. What can be achieved by the arrangement of the second connection layer at least partly in the depression is that the second connection layer can be at least partly shielded from the surrounding atmosphere.

Furthermore, an adhesive and/or a getter material can be arranged in the covering region of the second substrate. The getter material used can preferably be an oxidizable and/or moisture-binding material which can react with oxygen and moisture and in the process bind these substances which are harmful to the organic functional layer sequence and which can, for example, still diffuse in extremely small quantities through a second connection layer composed of adhesive. Readily oxidizing materials used include, in particular, metals from the group of alkali and alkaline earth metals and oxides therewith, for example calcium oxide and/or barium oxide, as chemisorbing materials. Furthermore, other metals such as, for example, titanium or oxidizable nonmetallic materials are also suitable. Furthermore, rigorously dried zeolites are also suitable as physisorbing materials.

The getter material can be applied to the covering region of the second substrate directly or in a mixture composed of the getter material and adhesive, wherein the getter material can in this case be dispersed for example in particle form in the adhesive. The adhesive can comprise one of the adhesives described above in connection with the second connection layer. In particular in the case described below where the adhesive is not arranged at a distance from the organic functional layer sequence, it can comprise an epoxide or be composed of an epoxy resin, which for example do not damage the cathode materials mentioned in connection with the embodiments of the organic functional layer sequence. For a getter material/adhesive mixture it is advantageous if the particles of the getter material are ground so finely that the particles can neither lead to mechanical damage to the organic functional layer sequence, for example the cathode, nor influence the second connection layer between the first connection layer and the first substrate.

In particular, the getter material and/or the adhesive can be applied before method step F and after the process of vitrifying the first glass solder material in method step D. This can mean that the getter material and/or the adhesive are/is arranged on that side of the second substrate on which the first connection layer is also arranged, such that after the process of connecting the first and second substrates in method step F, the getter material and/or the adhesive are/is arranged together with the organic layer sequence in the cavity enclosed by the first and second substrates and the first and second connection layers. After method step F the getter material and/or the adhesive can be arranged at a distance from the organic functional layer sequence, such that a residual cavity is still situated between the first and second substrates, which cavity can be filled with gas, for example. In this case, the distance can be adjustable principally by means of the thickness of the getter material and the first thickness of the first connection layer. The second substrate can additionally have a cavity, that is to say a depression, in the covering region, in which the getter material and/or the adhesive are/is at least partly arranged and thus for example suitably spaced apart from the organic functional layer sequence. As an alternative thereto, the getter material and/or the adhesive can fill the entire enclosed cavity around the organic functional layer sequence.

As a result of the getter material being arranged at a distance from the organic functional layer sequence, oxygen and/or moisture diffusing into the cavity can be absorbed areally by the getter material, which can result in a higher pump capacity, as it is called, until defects occur in the organic functional layer sequence. By contrast, if the adhesive is arranged in the entire cavity, for example, this can simultaneously form the second connection layer. If monodisperse nanoparticles are used as getter material, then the second connection layer can even be formed by a getter material/adhesive mixture. In this case, the getter material concentration in the adhesive then has to be so low that the getter material particles do not touch one another and cannot form a diffusion channel.

Particularly in connection with a second connection layer composed of a second glass solder material, but also in the case of a suitably impermeable second connection layer composed of an adhesive, it can also be possible that, in comparison with known OLEDs, less or no getter material at all has to be arranged in the covering region of the second substrate. In this case, a permanently impermeable connection between the first and second substrates can be producible, which can enable a long lifetime of the organic optoelectronic component without a getter material being necessary.

Furthermore, in the method step the organic functional layer sequence can be formed with at least one barrier layer which covers the organic functional layer sequence. Thus, the organic functional layer sequence can be encapsulated with a stack of oxide, nitride and/or oxynitride layers, for instance silicon nitride (SiNₓ) and/or silicon oxide (SiO₂) layers, deposited in a plasma-enhanced chemical vapor deposition (PECVD) method or by sputtering. Such a layer combination of SiNₓ (N) and SiO₂ (O) can be repeated many times, thereby closing individual diffusion channels, each individual one of which could lead to a visible defect in the active area of the organic functional layer sequence. However, even in the case of a stack of NONONON there can still be individual non-impermeable point defects. If such a type of organic functional layer sequence with barrier layer is then additionally encapsulated by means of the second substrate and the first and second connection layers by the method described above, the diffusion path of water and oxygen can be lengthened to an extent such that the aging of the organic optoelectronic component as a result of water action is delayed to such an extent that the component can withstand a typical moisture test at a temperature of 60° C. and with 90% relative air humidity for 504 hours without giving rise to a water-dictated defect that becomes larger than 400 μm, for instance.

In particular, the organic optoelectronic component can also comprise a combination of the getter material and the barrier layer.

In accordance with a further embodiment for producing an organic optoelectronic component, a method comprises the following steps:

A) providing a first substrate having an active region and a first connection region surrounding the active region,

B) providing a second substrate having a covering region and a second connection region surrounding the covering region,

C) applying a first connection layer composed of a first glass solder material directly on the first substrate in the first connection region,

D) vitrifying the first glass solder material of the first connection layer on the first substrate,

D′) forming an organic functional layer sequence in the active region of the first substrate,

E) applying a second connection layer on the vitrified first connection layer or on the second connection region of the second substrate, and

F) connecting the first substrate to the second substrate in such a way that the second connection layer connects the second connection region to the first connection layer.

In comparison with the method described above, it is thus also possible to form and vitrify the first connection layer on the first substrate. By virtue of the fact that the organic functional layer sequence is applied only after the process of vitrifying the first connection layer on the first substrate in method step D′, it is possible to avoid damage to the organic functional layer sequence as a result of method step D. In this case, the organic optoelectronic component that can be produced in this way can have the following features:
a first substrate having an active region and a first connection region surrounding the active region, wherein an organic functional layer sequence (3) is formed in the active region,
a second substrate having a covering region above the active region and a second connection region, surrounding the covering region above the first connection region, and
a first and a second connection layer between the first and second connection regions,

wherein
the first connection layer directly adjoins the second connection region and is composed of a first glass solder material, and
the second connection layer connects the first connection layer to the first connection region.

Such an organic optoelectronic component has an opposite construction with regard to the spatial arrangement of the first and second connection layers relative to the organic functional layer sequence in comparison with the organic optoelectronic component described further above. The method and the component that can be produced thereby can have one or more of the above-described features, properties, embodiments and combinations thereof.

In the methods described here, an organic optoelectronic component having the properties and features described above can be produced which has a sealing section, that is to say has a first and a second connection layer between the first and the second substrates in the first and second connection regions, with a variable and freely selectable proportion of the first and second connection layers. The width and first thickness of the first connection layer and also the width and second thickness of the second connection layer can be, in each case and also in the respective ratios relative to one another, freely selectable for the purpose of optimization of material outlay and of impermeability. The second thickness of the second connection layer can be reduced in comparison with the first thickness of the first connection layer to the extent necessary for an impermeable connection between the first and second substrates. The thinner the second connection layer, the lower the risk that oxygen and/or moisture will penetrate into the organic optoelectronic component, and the longer the attainable lifetime of the component can thus be.

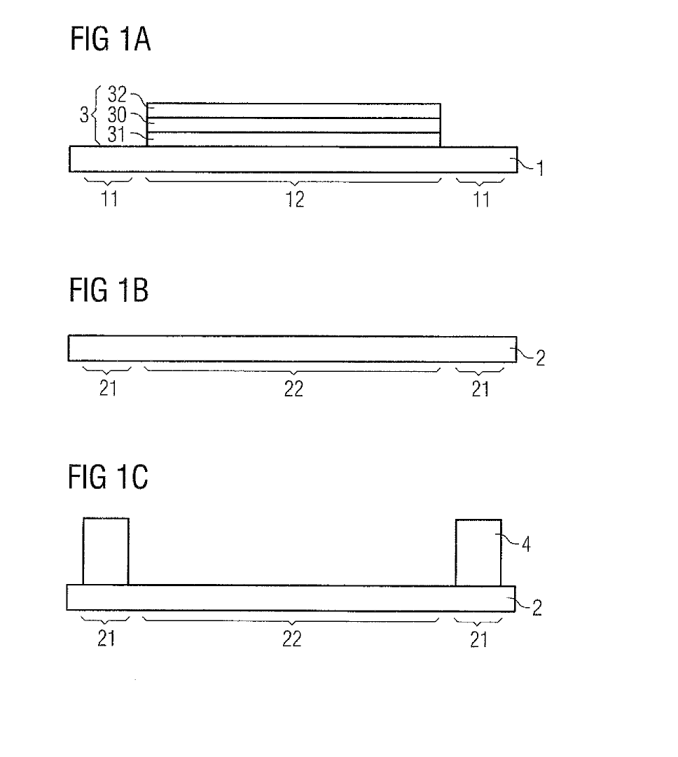

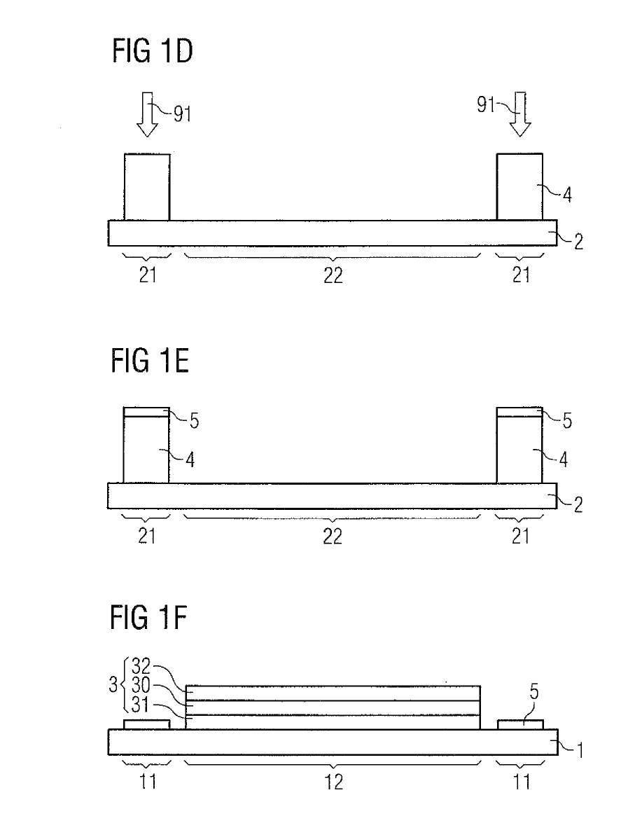

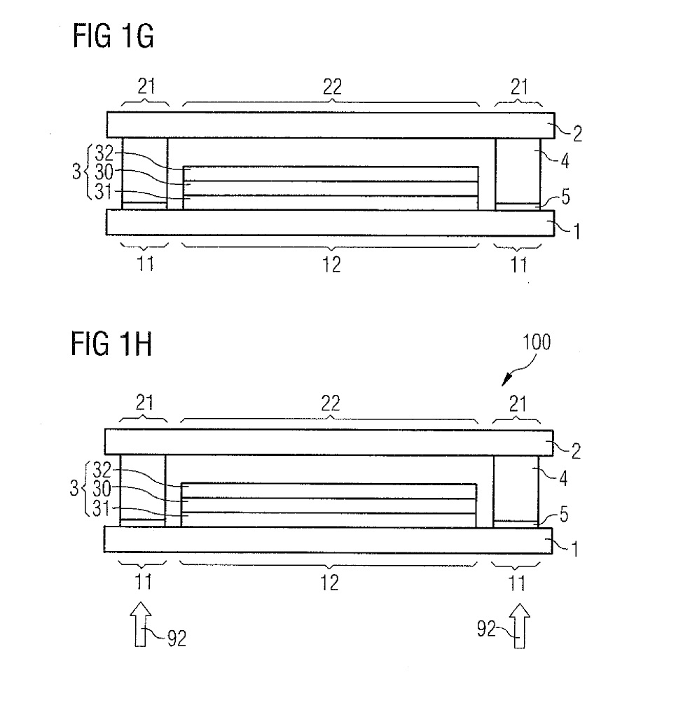

Further advantages and advantageous embodiments and developments of the invention will become apparent from the embodiments described below in connection with FIGS. 1A to 6.

In the figures:

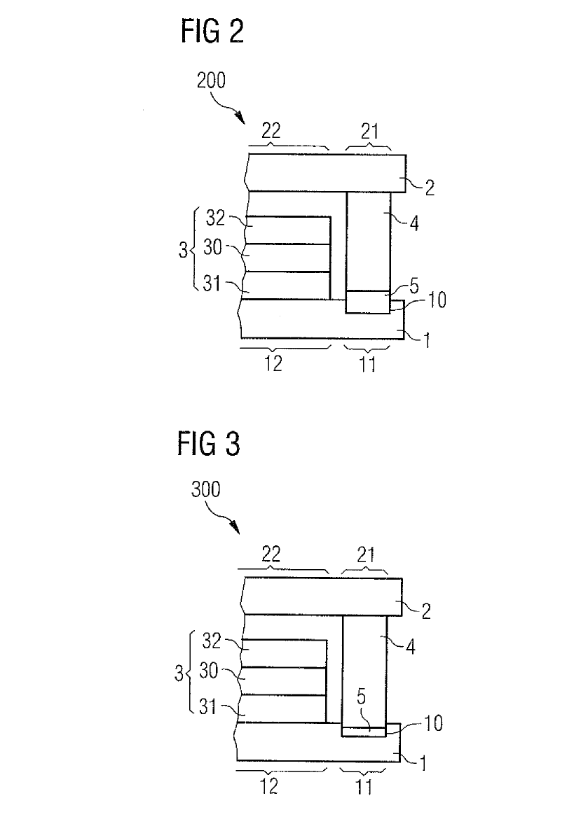

FIGS. 1A to 1H show schematic illustrations of a method for producing an organic optoelectronic component in accordance with one exemplary embodiment, and FIGS. 2 to 6 show schematic illustrations of organic optoelectronic components in accordance with further exemplary embodiments.

In the exemplary embodiments and figures, identical or identically acting constituent parts can in each case be provided with the same reference symbols. The elements illustrated and their size relationships among one another should not be regarded as true to scale, in principle; rather, individual elements such as, for example, layers, structural parts, components and regions may be illustrated with exaggerated thickness or size dimensions in order to enable better illustration and/or in order to afford a better understanding.

FIGS. 1A to 1H show a method for producing an organic optoelectronic component 100 in accordance with one exemplary embodiment. In this case, in a first method step A in accordance with FIG. 1A, a first substrate 1 is provided, which has an active region 12 and, surrounding the latter, a first connection region 11. The substrate 1 is composed of glass in the exemplary embodiment shown.

An organic functional layer sequence 3 is formed in the active region 12, said organic functional layer sequence being embodied as an organic light-emitting diode (OLED) in the exemplary embodiment shown. It comprises on the substrate 1 a first electrode 31, on which an active organic layer 30 comprising a plurality of organic functional layers is applied. A second electrode 32 is applied above the active organic layer 30. The first electrode 31 and the second electrode 32 are formed as anode and as cathode, respectively, which are suitable for injecting holes and electrons into the active layer 30.

The active layer 30 has at least one electroluminescent layer suitable for emitting electromagnetic radiation by recombination of the injected electrons and holes during operation. In addition, the active layer 30 can have further organic functional layers, for instance at least one hole and/or one electron transport layer, and/or further features from among the features described in the general part. Furthermore, the organic functional layer sequence 3 can also be formed as a multilayer OLED having a plurality of electroluminescent layers arranged one above another and further organic functional layers respectively arranged therebetween. The functional layers of the active layer 30 can comprise organic materials in the form of polymers or small organic molecules as described in the general part.

In the exemplary embodiment shown, the first and second electrodes 31, 32 are in each case embodied in transparent fashion and comprise, for example, a TCO and/or a metal as described in the general part. As a result, the organic optoelectronic component 100 that can be produced by the method described hereinafter is embodied as a bottom emitter and as a top emitter, such that the electromagnetic radiation generated in the active layer 30 during operation can be emitted both through the first substrate 1 and through the second substrate 2 described hereinafter, and the organic optoelectronic component 100 is formed as a transparent OLED that emits on both sides.

Alternatively or additionally, the organic functional layer 3 can also be formed as a radiation-detecting layer sequence, for instance as an organic photodiode or solar cell, and/or have further organic electronic structural parts such as thin-film transistors, for instance.

In a second method step B in accordance with FIG. 1B, a second substrate 2 composed of glass is provided, which has a covering region 22 and, surrounding the latter, a second connection region 21. In a further method step C in accordance with FIG. 1C, a first connection layer 4 comprising a first glass solder material is applied to the second connection region 21, wherein the first glass solder material is preferably lead-free and comprises materials and compositions as described in the general part. In this case, the first glass solder material is applied in the form of a so-called glass solder bead or paste in a shapeable state for example by dispensing, screen printing or stencil printing. The first connection layer 4, which can comprise non-cured binders and solvents added for application purposes, encloses the covering region 22 along the second connection region 21.

In a further method step D in accordance with FIG. 1D, the first connection layer 4 is vitrified, which is indicated by the arrows 91. For this purpose, the first connection layer 4 together with the second substrate 2 is dried, subjected to binder removal, sintered and vitrified in a furnace by the supply of heat. In this case, the first connection layer 4 combines with the second substrate 2 in the second connection region 21, wherein the first glass solder material, by means of suitable additives, can have a coefficient of thermal expansion adapted to the second substrate 2. Stress-free fusing of the second substrate 2 with the first connection layer 4 is possible as a result. In this case, the thickness and width of the first connection layer 4 are variably selectable and adjustable without complicated glass processing of the second substrate 2 as early as during the application of the first connection layer 4. Since the organic functional layer sequence 3 is not affected by the vitrifying process of the first glass solder material, the vitrifying 91 of the first connection layer 4 can be carried out under optimum conditions. As an alternative or in addition to the furnace process described here, the first connection layer 4 can also be vitrified by means of irradiation with light in the ultraviolet to infrared wavelength range, wherein, in this case, too, vitrifying 91 can be effected under optimum conditions for a hermetically impermeable connection of the first connection layer 4 to the second substrate 2, without consideration having to be given to the organic functional layer sequence 3.

For improving the adhesion and/or minimizing the thickness of the second connection layer 5 described hereinafter, the first connection layer 4 can be planarized on the surface facing away from the second substrate 2 after vitrifying 91. This can be effected by plane grinding, for example. As an alternative thereto, a planarizing shaping can already be effected during or before the vitrifying 91 in the furnace process.

In a further method step E in accordance with FIG. 1E, a second connection layer 5 is applied on that surface of the first connection layer 4 which faces away from the second substrate 2 and extends circumferentially around the covering region 22. In this case, the second connection layer 5 comprises a preferably filler-free, organic curable adhesive, in particular an epoxy resin. While the first connection layer 4 has a first thickness, which is chosen with regard to the desired distance between the first and second substrates 1 and 2 in the finished organic optoelectronic component 100, the second connection layer 5 can be applied with a second thickness, which is significantly smaller than the first thickness. In particular, the second thickness is less than or equal to one fifth and particularly preferably less than or equal to one tenth of the first thickness. Advantageously, the second thickness of the second connection layer 5 can be reduced to an extent such that an impermeable composite connection between the first and second substrates 1, 2 is indeed still just possible. For this purpose, the second connection layer 5 can have a second thickness of from a few atomic layers up to a few micrometers. The thinner the second connection layer 5 comprising the organic curable adhesive in this case, the lower the diffusion rate of moisture and oxygen through the adhesive of the second connection layer 5 and the longer the lifetime of the organic optoelectronic component 100 thus produced can be.

As an alternative or in addition to the application of the second connection layer 5 on the vitrified first connection layer 4, the second connection layer 5, in method step E, can also be applied on the first connection region 11 of the first substrate 1, as is shown in FIG. 1F.

In a further method step F in accordance with FIG. 1G, the second substrate 2 is arranged above the first substrate 1 and connected to the latter by means of the first and second connection layers 4, 5. For this purpose, the covering region 22 and the active region 12 and also the first and second connection regions 11, 21 are respectively arranged one above another, such that the second connection layer 5 connects the first connection layer 4 to the first connection region 11 of the first substrate 1. In this case, as indicated in FIG. 1G, the widths of the first and second connection layers 4, 5 can be at least approximately identical. As an alternative thereto, the second connection layer 5, after the joining-together process, can, for example, also have a larger width than the first connection layer 4 and, for example, form an edge that encloses the interface between the first and second connection layers 4, 5.

By means of a further method step for producing the organic optoelectronic component 100 in accordance with FIG. 1H, the second connection layer 5 is cured. This can be effected, as is indicated by the arrows 92 in FIG. 1H, by heat- or radiation-induced crosslinking of the organic curable adhesive in the second connection layer 5. As an alternative thereto, the adhesive can also be crosslinked in a chemically initiated fashion and be cured, for instance according to the principle of a multicomponent adhesive. The energy input and heat input to the organic functional layer sequence 3 during the curing 92 of the second connection layer 5 are low enough, on account of the small second thickness of the second connection layer 5, not to damage the latter.

As an alternative to a second connection layer 5 comprising an organic curable adhesive, in method step E, as second connection layer 5 it is also possible to apply a second glass solder material on the first connection layer 4 and/or on the first connection region 11 of the first substrate 1. In this case, the advantages mentioned above also apply to the use of a second glass solder material instead of the adhesive. In particular, after method step F, for example by means of a focused laser beam, the second glass solder material of the second connection layer 5 can be melted and vitrified in a targeted manner, wherein the respective heat input to the first substrate 1, the organic functional layer sequence 3 and the first connection layer 4 can be kept low. Particularly preferably, the second glass solder material softens at lower temperatures than the first glass solder material. As in the case of the organic curable adhesive as second connection layer 5, in the case of the second glass solder material, too, a small second thickness of the second connection layer 5 is advantageous since the latter can be melted and vitrified all the more easily, the thinner it is. In this case, depending on the requirements, the second thickness of the second connection layer 5 can range from a few atomic layers up to a few micrometers. In order to improve the targeted melting and vitrifying of the second connection layer 5 comprising the second glass solder material, the second connection layer 5 can additionally also comprise a material that can absorb electromagnetic radiation, while the first connection layer 4 is free of said material. The absorbent material preferably comprises a metal or a metal compound, preferably a metal oxide. In particular, this can be a rare earth metal or a transition metal, for example vanadium, iron, copper, chromium and/or neodymium, or an oxide thereof.

As is shown in FIG. 1H, by means of the method described here, it is possible to produce an organic optoelectronic component 100 in which the second thickness of the second connection layer 5 is significantly reduced in comparison with the total thickness of the first and second connection layers 4, 5 and the connection between the first and second substrates 1, 2 is formed for the most part by the oxygen- and moisture-impermeable first connection layer 4 composed of the first glass solder material.

As an alternative to the method described above, the first connection layer 4 can also be applied in the first connection region 11 of the first substrate and then be vitrified. In order that the organic functional layer sequence 3 is not damaged by the vitrifying of the first connection layer 4, it is applied only after vitrifying. The method then has, in comparison with the method described previously, the following steps, in particular:

A) providing a first substrate 1 having an active region 12 and a first connection region 11 surrounding the active region 12,

B) providing a second substrate 2 having a covering region 22 and a second connection region 21 surrounding the covering region 22,

C) applying a first connection layer 4 composed of a first glass solder material directly on the first substrate 1 in the first connection region 11,

D) vitrifying the first glass solder material of the first connection layer 4 on the first substrate 1,

D′) forming an organic functional layer sequence 3 in the active region 12 of the first substrate 1,

E) applying a second connection layer 5 on the vitrified first connection layer 4 or on the second connection region 21 of the second substrate 2, and

F) connecting the first substrate 1 to the second substrate 2 in such a way that the second connection layer 5 connects the second connection region 21 to the first connection layer 4.

The following exemplary embodiments show further modifications of the organic optoelectronic component 100 in accordance with the exemplary embodiment described previously. In this case, the following description is therefore restricted principally to the description of the respective differences. Elements and features not described are embodied as described in the previous exemplary embodiment and/or as described in the general part.

FIGS. 2 and 3 show organic optoelectronic components 200 and 300 in which the first substrate 1 has in the first connection region 11 a depression 10 surrounding the active region 12.

In accordance with the exemplary embodiment in FIG. 2, the depression 10 in this case has a depth that is less than the second thickness of the second connection layer 5. The depression 10 makes it possible to further increase the impermeability of the interface between the first substrate 1 and the second connection layer 5 on account of a longer permeation path for oxygen and moisture, wherein the width of the depression can be chosen independently of the width of the first connection layer. Furthermore, that proportion of the second connection layer 5 which directly adjoins the atmosphere surrounding the organic optoelectronic component 200 can be reduced.

In accordance with the exemplary embodiment in FIG. 3, the depression 10 has a depth that is greater than the second thickness of the second connection layer 5. As a result, the first connection layer 4 also extends into the depression 10, as a result of which the second connection layer 5 is enclosed by the substrate 1 and the first connection layer 4 apart from a gap in the edge region of the depression 10. As a result, it is possible to achieve a further reduction of the diffusion rate of oxygen and moisture through the second connection layer 5, particularly if the latter comprises adhesive, and through the interfaces between the second connection layer 5 and the substrate 1 and also between the second connection layer 5 and the first connection layer 4.

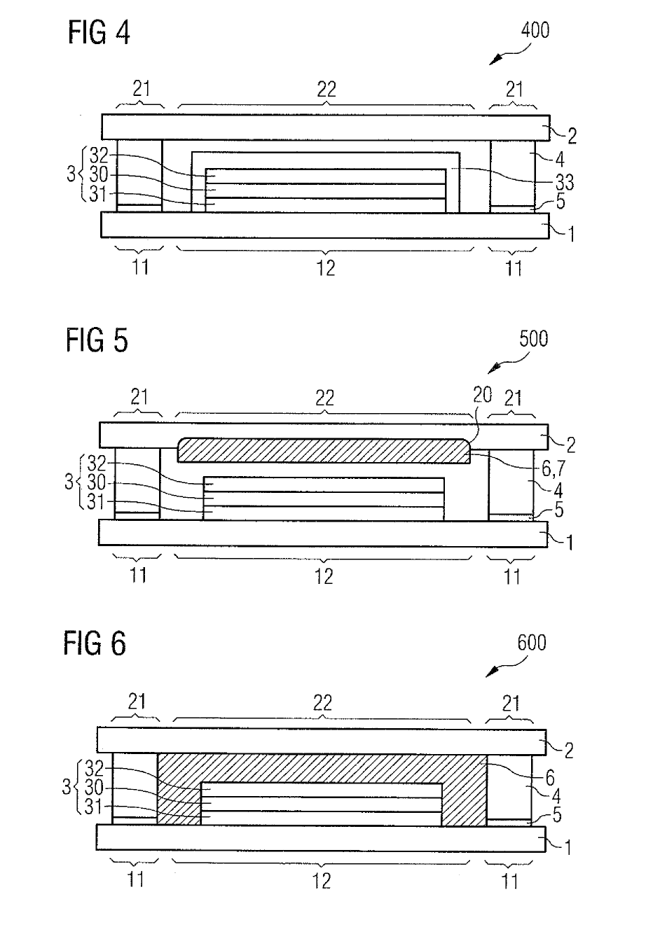

The exemplary embodiments in FIGS. 4 to 6 show organic optoelectronic components 400, 500 and 600 which have further additional measures for increasing the lifetime of the components, which can advantageously be used with the combination of first and second connection layers 4, 5 described here.

In the exemplary embodiment in accordance with FIG. 4, an organic functional layer sequence 3 with a barrier layer 33 is provided. The barrier layer 33 has a stack of silicon oxide and silicon nitride layers deposited by the PECVD method. The layer combination of SiNₓ (N) and SiO₂ (O) is repeated multiply, preferably at least twice, thereby closing individual diffusion channels, each individual one of which could lead to a visible defect in the active area of the organic functional layer sequence 3. Through the combination of the encapsulation by means of the barrier layer 33 and by means of the first and second connection layers 4, 5 and the second substrate 2, the organic optoelectronic component 400 can withstand a typical moisture test at a temperature of 60° C. and with 90% relative air humidity for 504 hours, without giving rise to a water- or oxygen-dictated defect which becomes larger than 400 micrometers in a length dimension.

The organic optoelectronic component 500 in accordance with the exemplary embodiment in FIG. 5 has in the covering region 22 of the second substrate 2, a cavity 20, that is to say a depression, in which a getter material 6 is arranged. The getter material 6 comprises an oxygen- and moisture-binding material as described in the general part, preferably BaO and/or CaO.

As an alternative to the exemplary embodiment shown, the getter material 6 can also be arranged without the cavity 20 in the covering region 22 of the second substrate 2. However, a smaller external structural height of the organic optoelectronic component 500 can advantageously be achieved by means of the cavity 20. The same also applies to the previous exemplary embodiments, such that the above-described organic optoelectronic components 100, 200, 300, 400 can also have a cavity 20 in the second substrate 2.

In the exemplary embodiment in accordance with FIG. 6, the organic optoelectronic component 600 has a mixture composed of a getter material 6 and an adhesive 7 in the entire cavity—formed by the first and second substrates 1, 2 and also the first and second connection layers 4, 5—around the organic functional layer sequence 3. In this case, the adhesive 7, which is preferably an epoxy resin, can simultaneously form the second connection layer 5. The getter material 6 is dispersed in the form of finely ground particles in the adhesive 7, particularly preferably in the form of monodisperse nanoparticles.

The features of the exemplary embodiments shown can also be combinable in order to achieve a further increase in the lifetime of the organic optoelectronic components.

The invention is not restricted to the exemplary embodiments by the description on the basis of said exemplary embodiments. Rather, the invention encompasses any novel feature and also any combination of features, which in particular includes any combination of features in the patent claims, even if this feature or this combination itself is not explicitly specified in the patent claims or exemplary embodiments.

1. A method for producing an organic optoelectronic component, comprising the following steps:
A) providing a first substrate having an active region and a first connection region surrounding the active region, wherein an organic functional layer sequence is formed in the active region;
B) providing a second substrate having a covering region and a second connection region surrounding the covering region;
C) applying a first connection layer composed of a first glass solder material directly on the second substrate in the second connection region;
D) vitrifying the first glass solder material of the first connection layer;
E) applying a second connection layer on the vitrified first connection layer or on the first connection region of the first substrate; and
F) connecting the first substrate to the second substrate in such a way that the second connection layer connects the first connection region to the first connection layer.

2. The method according to claim 1, wherein
in method steps C and D the first connection layer is formed with a first thickness, and
after method step F the second connection layer has a second thickness, which is less than or equal to one fifth of the first thickness.

3. The method according to claim 1, wherein the second connection layer comprises an organic curable adhesive, and the adhesive is cured after method step F.

4. The method according to claim 1, wherein the second connection layer comprises a second glass solder material, and the second glass solder material is vitrified after method step F.

5. The method according to claim 3, wherein the second connection layer comprises a material that absorbs an electromagnetic radiation, and the first connection layer is free of the absorbent material.

6. The method according to claim 1, wherein during or after method step D a surface of the first connection layer which faces away from the second substrate is planarized.

7. The method according to claim 1, wherein
in method step A the first substrate is provided in the first connection region with a depression surrounding the active region, and
after method step F the second connection layer is at least partly arranged in the depression.

8. The method according to claim 1, wherein an adhesive and/or a getter material is arranged in the covering region of the second substrate before method step F.

9. The method according to claim 1, wherein in method step A the organic functional layer sequence is formed with at least one covering barrier layer.

10. A method for producing an organic optoelectronic component, comprising the following steps:
A) providing a first substrate having an active region and a first connection region surrounding the active region;
B) providing a second substrate having a covering region and a second connection region surrounding the covering region;
C) applying a first connection layer composed of a first glass solder material directly on the first substrate in the first connection region;
D) vitrifying the first glass solder material of the first connection layer on the first substrate;
D′) forming an organic functional layer sequence in the active region of the first substrate;
E) applying a second connection layer on the vitrified first connection layer or on the second connection region of the second substrate; and
F) connecting the first substrate to the second substrate in such a way that the second connection layer connects the second connection region to the first connection layer.

11. An organic optoelectronic component, comprising:
a first substrate having an active region and a first connection region surrounding the active region, wherein an organic functional layer sequence is formed in the active region;
a second substrate having a covering region above the active region and a second connection region, surrounding the covering region above the first connection region; and
a first and a second connection layer between the first and second connection regions,
wherein
the first connection layer directly adjoins the second connection region and is composed of a first glass solder material, and
the second connection layer connects the first connection layer to the first connection region.

12. The component according to claim 11, wherein
the first connection layer has a first thickness, and
the second connection layer has a second thickness, which is less than or equal to one fifth of the first thickness.

13. The component according to claim 11, wherein the second connection layer comprises an organic curable adhesive.

14. The component according to claim 11, wherein
the second connection layer comprises a material that absorbs an electromagnetic radiation, and
the first connection layer is free of the absorbent material.

15. The component according to claim 11, wherein
the first substrate has in the first connection region a depression surrounding the active region, and
the second connection layer is at least partly arranged in the depression.

16. The component according to claim 15, wherein the depression has a depth that is greater than the second thickness of the second connection layer.

17. The component according to claim 16, wherein the first connection layer extends into the depression.

18. The component according to claim 11, wherein the second connection layer comprises a second glass solder material.

19. The method according to claim 4, wherein
the second connection layer comprises a material that absorbs an electromagnetic radiation, and
the first connection layer is free of the absorbent material.
